(19) United States
(12) Patent Application Publication
(10) Pub. No.: US 2005/0206447 A1
(43) Pub. Date: Sep. 22, 2005

(54) Method to prevent saturation in power amplifier control loop

(76) Inventors: Ryo Yamazaki, Suwanee, GA (US); William Noellert, Atlanta, GA (US)

Correspondence Address: SMITH FROHWEIN TEMPEL GREENLEE BLAHA, LLC, P.O. BOX 88148, ATLANTA, GA, 30356, US

(21) Appl. No.: 10/803,771

(22) Filed: Mar. 18, 2004

(51) Int. Cl. H03G 3/20

(52) U.S. Cl. 330/129

(57) ABSTRACT

When a power amplifier control loop operates near or in saturation, the quality of the output signal can be degraded and an over current condition can occur. To prevent this, the output signal of the power amplifier is detected, converted to digital, and then converted into the frequency spectrum by means of a Fast Fourier Transform. The spectral characteristics of the output signal are analyzed to determine if the power amplifier control loop is approaching or operating in saturation mode. This determination is made by looking at the power of the output signal at various frequencies. If the output at these frequencies exceeds a threshold value, the power amplifier control loop is approaching saturation. In this situation, the output of the power amplifier can be adjusted to prevent loop saturation. This can be accomplished by reducing the supply voltage to the power amplifier or adjusting the bias voltage.

### CROSS-REFERENCE TO RELATED APPLICATIONS

This application is related to U.S. patent application Ser. No ______ entitled “METHOD TO CONTROL THE SUPPLY POWER BEING PROVIDED TO A POWER AMPLIFIER” filed on the same date as this application and commonly assigned to the assignee of this application, which application is incorporated herein by reference in its entirety.

### TECHNICAL FIELD

The present invention is directed towards radio frequency transmission technology and, more specifically, towards a technique to detect and prevent saturation in a power amplifier control loop of a transmitter and thereby, reduce spurious outputs caused by loop saturation.

### BACKGROUND

Cellular telephone technology has greatly advanced since its inception in the early 80's. Today, the Global System for Mobile communication (GSM) is one of the more prominent technologies being deployed in cellular systems throughout the world. GSM is a digital cellular communications system that was initially introduced in the European market but it has gained widespread acceptance throughout the world. It was designed to be compatible with ISDN systems and the services provided by GSM are a subset of the standard ISDN services (speech is the most basic).

The operational components of a GSM cellular system include mobile stations, base stations, and the network subsystem. The mobile stations are the small, hand-held telephones that are carried by subscribers. The base station controls the radio link with the mobile stations and the network subsystem performs the switching of calls between the mobile and other fixed or mobile network users.

The GSM transmission technology utilizes the Gaussian Minimum Shift Keying form of modulation (GMSK). In this modulation scheme, the phase of the carrier is instantaneously varied by the modulating signal. Some of the important characteristics of GMSK modulation are that the output signal has a constant envelope, a relatively narrow bandwidth and a coherent detection capability. However, the most important characteristic of these characteristics is the constant envelope. Signals that have a constant envelope are more immune to noise than signals that have varying amplitudes.

In addition, because GMSK modulation does not include amplitude components, the transmitter does not require the use of a linear power amplifier. Power amplifiers operating in the non-linear region typically deliver much higher efficiencies than when they are operating in the linear region. Cellular modulation technologies that include amplitude components, such as CDMA (IS-95, TDMA (IS-136) and EDGE, are highly dependent upon maintaining linearity of the power amplifier. Thus, mobile stations based on such technology typically utilize an isolator at the output of the power amplifier, or implement other methods to preserve linearity of the power amplifier. GMSK technology does not require an isolator, which is a great benefit due to the size and cost of a typical isolator; however, the absence of such an isolator creates additional technological problems in a GSM system.

In GSM technology, the output of the power amplifier is typically fed into a harmonic filter, a transmit/receive switch and an antenna. It is not uncommon for a mismatch condition of as high as 10:1 Voltage Standing Wave Ration (VSWR) or worse to be present at the antenna—which has a very significant affect on the output load impedance seen by the power amplifier. Unfortunately, power amplifiers are typically designed to operate with a constant load impedance of 50 Ohms. When the VSWR is changing at the output of a power amplifier, the load impedance at the output of the power amplifier fluctuates. Thus, the efficiency of operation for a power amplifier is degraded as the VSWR increases and the load impedance changes.

When a power amplifier is operating at an efficiency level that is lower than what it was designed for, an over current condition can be created. Such a condition can be catastrophic in that it puts unnecessary drain onto the battery and thus reduces the time required between battery charge cycles. In addition, as the efficiency of the power amplifier is decreased, the output spectrum can degrade and the spurious output level can exceed the levels required in the specifications for GSM technology. Thus, there is a need in the art for a system that prevents loop saturation in a power amplifier system, which results in a decrease in the efficiency of a power amplifier operating in a GSM system. Similarly, there is a need in the art to prevent such power amplifiers from drawing excessive amounts of current and degrading the output spectrum as a result of a decrease in efficiency.

Three techniques have been introduced to the market to address this need in the art; however, as is shown in this document, these techniques fall short of being a viable solution. FIG. 1 is a circuit diagram illustrating the most conventional method. This method utilizes a power coupler 101 and a detector 102. In operation, this circuit detects the output power of the power amplifier 103 and compares the detected voltage 104 with a reference voltage 105 by the use of an integrator 106 to generate an error voltage 107. The error voltage 107 is then applied to the power amplifier 103 to close the loop and adjust the output power of the power amplifier 103. This is a true closed loop system that tracks power very accurately. Because this system detects the power output of the power amplifier 103, the output power variation is less of a concern, however, the over current condition can affect the battery life and spectrum purity.

FIG. 2 is a circuit diagram illustrating a similar method as the one illustrated in FIG. 1. In this method, the circuit detects the collector/drain current 201 being provided to the power amplifier 203 instead of detecting the output power directly. This is also a closed loop system but does not offer the level of accuracy seen in the power detector system of FIG. 1. This system is very effective at preventing the over current condition, but the output power variation control is not as accurate as the power detection method shown in FIG. 1.

FIG. 3 is a circuit diagram illustrating a quasi-closed loop system that utilizes a pass transistor in series with the collector (drain) supply. The pass transistor 301 regulates the collector (drain) voltage to regulate the Vcc (Vdd) 302. This method can be highly accurate and stable as long as the battery voltage stays above a threshold and the output is presented with a 50 ohm load. Unfortunately, these ideal conditions are not guaranteed in handset applications. Both the output power and current variations can be quite high when a mismatch load is presented. Because of the voltage drop caused by the pass transistor 301, the battery threshold voltage is usually higher than that in the methods illustrated in FIGS. 1 and 2.

The techniques illustrated in FIGS. 1-3 are insufficient in addressing the issues associated with GSM using GMSK modulation. One of the reasons for this insufficiency is that the prior art systems expect to operate against a matched load of 50 ohms. In GSM products, such an ideal condition is not available and the load impedance can greatly fluctuate. The present invention provides a novel solution for GSM type transmitters.

### SUMMARY OF THE INVENTION

The present invention provides a solution to the deficiencies in the current art by providing a power control circuit that limits spurious outputs due to switching transients and/or over current conditions from occurring in the power amplifier section of GSM type transmitters. Spurious conditions occur when the control loop of the power amplifier of a transmitting device approaches saturation. The present invention operates to detect this condition and adjust the control loop of the power amplifier system to prevent it from entering saturation. The present invention detects the output of the power amplifier and converts the detected analog signal into a digital signal. The present invention then transforms the digital signal into the frequency domain. In one embodiment this is accomplished by using Fast Fourier Transform. The spectral characteristics of the signal are then analyzed to determine if the output level at various frequencies is approaching or exceeding threshold values. Such a condition indicates that the control loop of the power amplifier is approaching saturation. When this condition occurs, the present invention limits the output of the power amplifier by either reducing the supply voltage to the power amplifier or adjusting the bias voltage. Thus, the present invention provides a system and method to control the output of a power amplifier without the need for an isolator. The present invention can be implemented using discrete components or circuits or may be incorporated in a base band ASIC.

### BRIEF DESCRIPTION OF THE DRAWINGS

FIG. 1 is a circuit diagram illustrating the most conventional method for controlling the output power of a power amplifier.

FIG. 2 is a circuit diagram illustrating a similar method as the one illustrated in FIG. 1 for controlling the output power of a power amplifier.

FIG. 3 is a circuit diagram illustrating a quasi-closed loop system that utilizes a pass transistor in series with the collector (drain) supply for controlling the supply power provided to a power amplifier.

FIG. 4 is a circuit diagram that can be incorporated into a GSM type transmitter to provide the power control of the present invention.

FIG. 5A illustrates a ramp up and ramp down of the transmitter that is within the GSM specifications or at nominal conditions.

FIG. 5B shows the frequency spectrum of the output signal during a ramp up or ramp down that is within the GSM specification.

FIG. 5C is a plot of an actual measurement of the output power spectrum of an in-specification GSM transmitter.

FIG. 6A illustrates a ramp up and ramp down of a transmitter that is not within the GSM specifications.

FIG. 6B shows the frequency spectrum of the output signal during a ramp up or ramp down of FIG. 6A.

FIG. 6C is a plot of an actual measurement of the output power spectrum of an out-of-specification GSM transmitter.

FIG. 7 is a flow diagram illustrating the steps of one embodiment of the present invention.

### DETAILED DESCRIPTION

The present invention provides a power control circuit that limits spurious outputs due to switching transients and/or over current conditions by the power amplifier section of GSM type transmitters. In general, the present invention detects the output power envelop and performs an analog to digital conversion of the envelope. A processor than performs a Fast Fourier Transform on the digital signal to allow for an analysis of the spectrum characteristics of the signal. The amplitude of the detected spectrum can be analyzed at various critical frequencies to determine is the transmitted signal is within the parameters of the GSM specification. For instance, at 400 kHz, the GSM specification requires the amplitude of the signal to be below a particular threshold. When this threshold is exceeded, it is an indication that the spurious output caused by the switching transients may be violating the GSM specification. Although this technique does not directly detect over current conditions, the detection and correction of spurious outputs due to switching transients effectively prevents over current conditions from occurring.

Turning now to the figures in which like numbers refer to like elements, the present invention is described in greater detail.

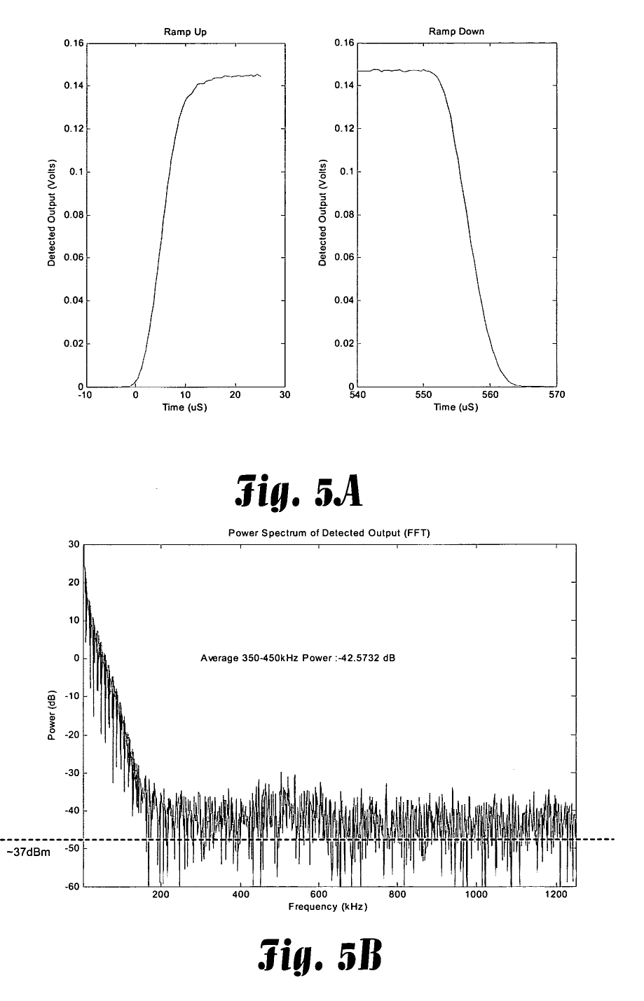

FIG. 4 is a circuit diagram that can be incorporated into a GSM type transmitter or other non-amplitude dependent type transmitter, to provide the power control of the present invention. Those skilled in the art will understand that the present invention can also be applied to amplitude dependent modulators such as during the ramp up and ramp down times. The power amplifiers system 400 includes a small coupler 401 and a detector at the output 411 of the power amplifier 410. In the illustrated embodiment, the coupler 401 is a small 30 dB coupler that couples about 1/1000^{ths} of the total output power of the power amplifier 410. The coupler 401 can be implemented within the printed circuit board without sacrificing the board space, and the expected loss of the coupler is approximately 0.1 dB (0.0043 dB coupling loss plus trace loss) or lower. The detector 402 generates a direct current (DC) voltage that represents the sampled output power from the power amplifier 410. The sampled output power is then filtered and processed by an analog-to-digital converter 403. A processor 440 then calculates the spectrum response as a result of ramping the radio frequency power by converting the digital signal into the frequency domain. In one embodiment this conversion can be achieved by performing a Fast Fourier Transform of the detected and converted signal.

The processor 440 then compares the amplitude of the spectrum to known good conditions. In the preferred embodiment, this comparison is performed at frequency of 400 kHz. It should be understood that the use of the 400 kHz offset is not mandatory, but it is simply provided as an example and is chosen as an example because this frequency is generally the first one to fail the GSM specification. When the level of the amplitude, relative to the power of the carrier signal, exceeds a preset value, the spurious output caused by switching transients is getting close to failing the GSM specification. Under this condition, the processor 440 can adjust the ramp voltage (Vramp) that is provided to the integrator 404.

The integrator 404, in coordination with pass transistor 405, the Vramp voltage reference and feedback circuit 406 operate to control the supply voltage provided to the power amplifier 410. Thus, if the supply voltage to the power amplifier is too high, the output of the feedback circuit 406 approaches the value of Vramp and the comparator/integrator 404 will operate to reduce the supply voltage. If the supply voltage to the power amplifier is too low, the output of the feedback circuit 406 drifts away from the value of Vramp and the comparator/integrator 404 will operate to increase the supply voltage. If the output spectrum of the power amplifier begins to deteriorate (i.e., the power spectrum at measured frequencies is too high) the present invention operates to change the value of the ramp voltage. For instance, if the output spectrum is too high at the measured frequency, the power amplifier is approaching saturation. By decreasing the value of Vramp, the DC power supplied to the power amplifier will be reduced and thereby move the power amplifier away from loop saturation. As a result, the spectrum at the measured frequency will again be reduced.

Those skilled in the art will realize that the present invention does not directly operate to detect over current conditions. However, it will be evident that the present invention, by detecting and correcting spurious energy levels due to switching transients, effectively operates to prevent over current conditions.

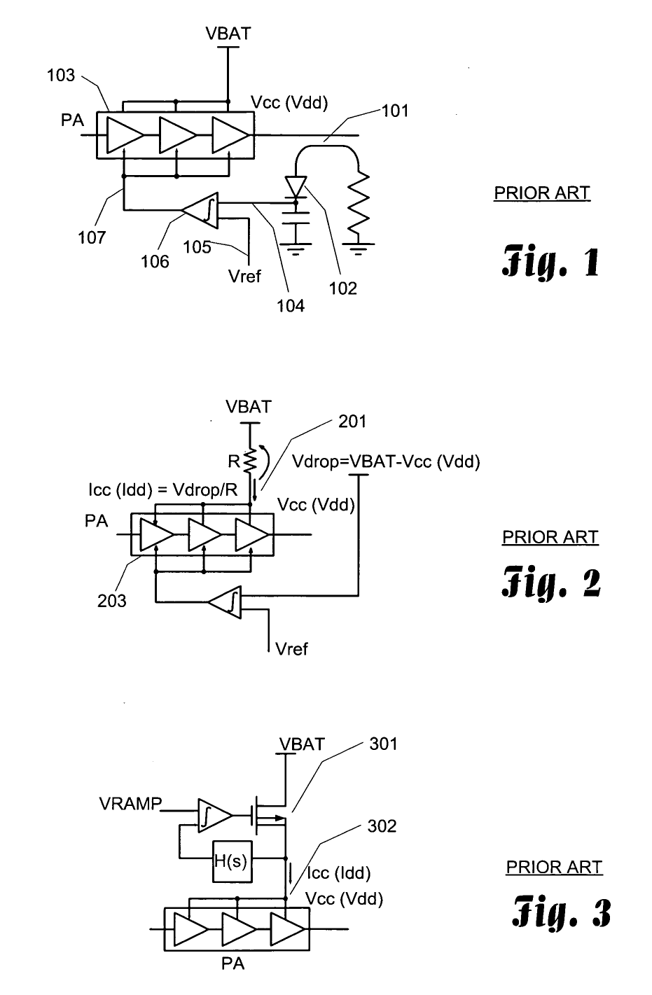

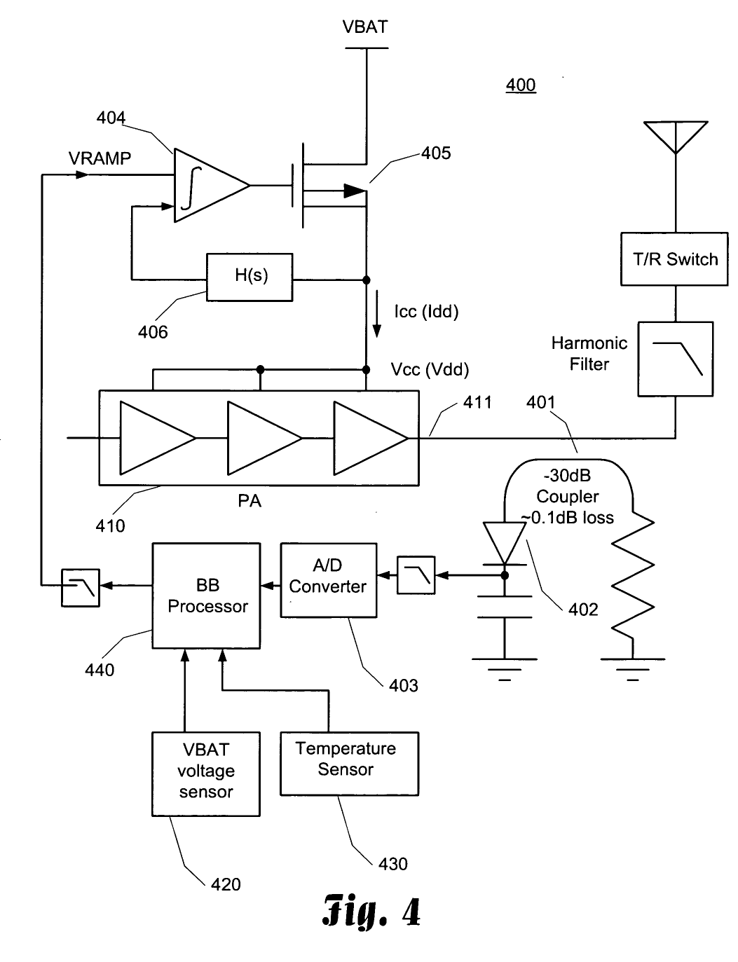

The present invention can be used in a variety of configurations and the circuit provided in FIG. 4 is just one example implementation. The present invention can be incorporated into the circuits illustrated in FIGS. 1-3 as well as other circuits. When the present invention is incorporated into the circuits of FIGS. 1 and 2, the present invention controls the output of the power amplifier by adjusting a bias voltage to the power amplifier.

In one embodiment, the present invention can be incorporated into a mobile telephone handset but, those skilled in the art will realize that the present invention is equally applicable for any transmission technology, even transmission technology that uses amplitude based modulation schemes.

The present invention is most applicable at higher power levels. Cellular systems typically have a range of power levels at which the mobile stations can transmit. At the higher power levels, the power amplifier is more prone to saturation. Thus, the present invention is particularly applicable to operation at the higher power levels.

The present invention is advantageous, among other reasons, because it can operate without the need for an isolator—which is a costly and bulky component. The coupler used in the present invention can be etched into the circuit board and thus, result in negligible cost and size impacts on the overall design of the mobile system.

In implementing the present invention, a preferred embodiment is to incorporate the processor 440 and the analog-to-digital converter 403 onto a single chip, typically referred to in the industry as the base band processor. However, the present invention can be implemented using discrete components, a combination of ASICs or other integrated circuits, as well as a combination of hardware and software/firmware components.

Those skilled in the art will be aware that GSM technology uses transmission bursts or time slot transmissions. During the allotted time slot, the GSM mobile station will transmit for a limited period of time and then the transmitter must be turned off again until the next time slot. During the beginning and ending portions of the time slot, the spurious transmissions due to switching transients of the transmitter are most prevalent. The beginning of the time slot is referred to in the industry as the ramp up and the ending of the time slot is the ramp down. The GSM specification has particular requirements on the amount of time that a transmitter can take to either ramp up or ramp down.

Conducting the Fast Fourier Transforms and analyzing the spectrum can be processor intensive. Thus, performing this process during the entire transmission period for a GSM transmitter is expensive with regards to processing time. Thus, to limit required amount of processing time, an embodiment of the present invention can focus on the ramp up and ramp down times of the time slot. Other embodiments focus on short periods of time during the transmit slot or the entire time slot.

FIG. 5A illustrates a ramp up and ramp down of the transmitter that is within the GSM specifications or at nominal conditions. FIG. 5B shows the frequency spectrum of the output signal during a ramp up or ramp down that is within the GSM specification. Please note that the actual scaling of the signals displayed in the FIGS. 5A and 5B has been skewed but, the purpose of this illustration is to provide a comparative view of signals that are within and without specification requirements. The average power between 350-450 kHz is shown to be −42.6 dB. FIG. 5C is a plot of an actual measurement of the output spectrum of a transmitter when the ramp up and ramp down of the transmitter is within the GSM specifications. In FIG. 5A, the output spectral power at a frequency of 400 kHz is illustrated to be approximately −37 dB, which correlates to the actual plot 510 in FIG. 5C of −29 dBm.

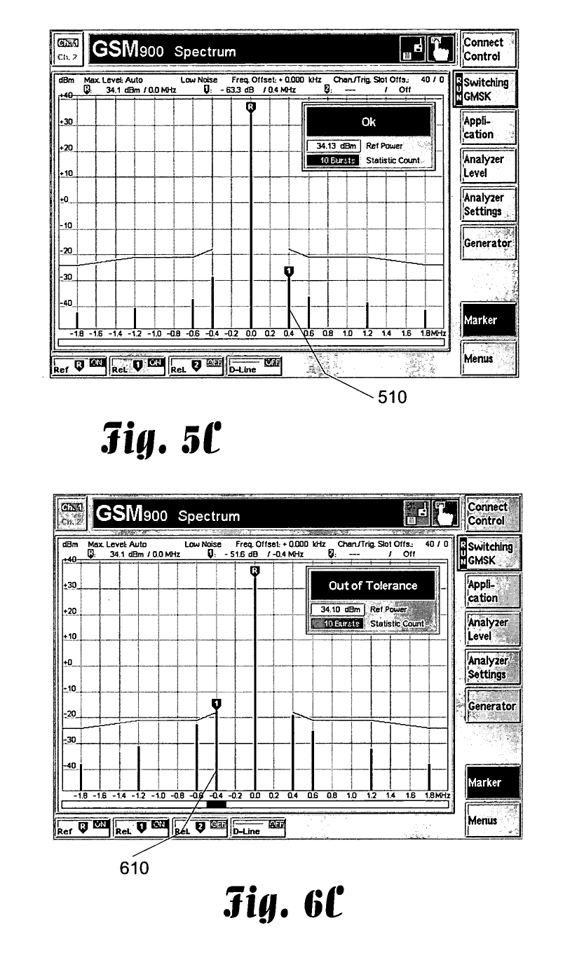

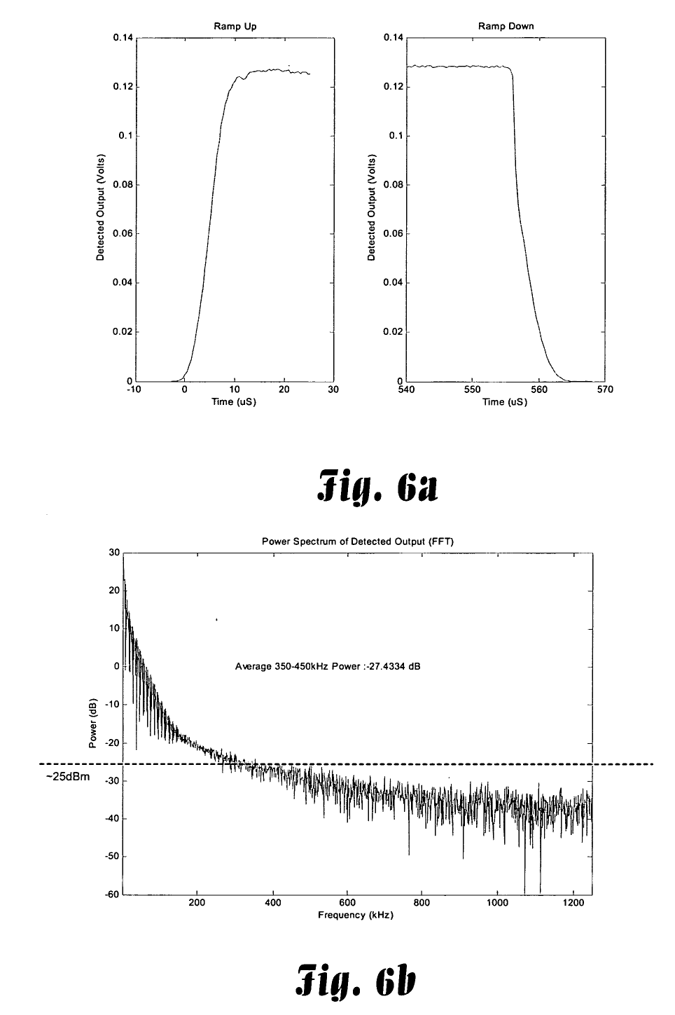

FIG. 6A illustrates a ramp up and ramp down of a transmitter that is not within the GSM specifications. FIG. 6B shows the frequency spectrum of the output signal during a ramp up or ramp down of FIG. 6A. As is illustrated, the output power at 400 kHz is greater than that of FIG. 5B and the average power between 350-450 kHz is −27.4 dB. FIG. 6C is a plot of an actual measurement of the output spectrum of a transmitter when the ramp up and ramp down of the transmitter is not within the GSM specifications. In FIG. 6A, the output spectral power at a frequency of 400 kHz is illustrated to be approximately −25 dB, which correlates to the actual plot 610 in FIG. 6C of −18 dBm.

Thus, the present invention can be used to measure the spectral characteristics of the output signal at either ramp up, ramp down or both to monitor the output signal. If the spectral power is increasing, it is evident that the power amplifier control loop is approaching saturation. When this occurs, the Vramp voltage can be decreased, thereby decreasing the power being provided to the power amplifiers 410. As a result, the switching transients are reduced and an over current condition is avoided.

The present invention may also incorporate other information to assist in limiting spurious outputs. Referring again to FIG. 4, a battery voltage sensor 420 and a temperature sensor 430 provide inputs to the processor. This information can be used by the processor in determining the optimal value for Vramp. For instance, the operating characteristics of a power amplifier, as well as other components can significantly vary over the operating temperature range. Thus, by detecting the temperature of components, the processor can more accurately determine an optimal value for Vramp. Likewise, as the battery providing power to a device begins to lose its charge, the operating characteristics of the various components can change. Thus, by detecting and monitoring the voltage level of the battery, the processor can more accurately determine an optimal value for Vramp.

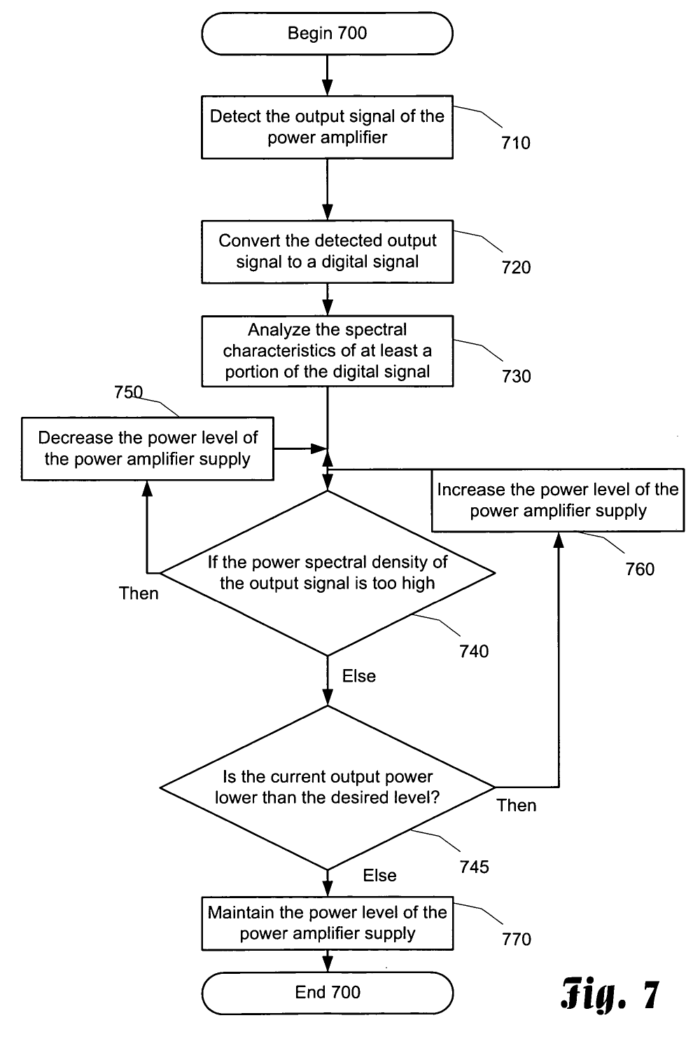

FIG. 7 is a flow diagram illustrating the steps of one embodiment of the present invention. The process 700 begins by detecting the output signal of the power amplifier 410 at step 710. This assumes that the circuit is already in operation and the processor 440 has determined and set an initial value for Vramp. At step 720, the detected output signal is converted into a digital signal. At step 730, the spectral characteristics of the digital signal, or at least a potion of the digital signal are analyzed. As previously noted, it is not necessary to analyze the entire frequency spectrum of the output signal, nor is it necessary to analyze the output signal during the entire time that the transmitter is active. However, at this step the output signal is analyzed to determine if the power spectral density is exceeding or approaching the specification limitations. At decision block 740, if the power spectral density is too high, then processing continues at step 750 where the power level of the power amplifier supply is reduced. In the embodiment illustrated in FIG. 4, this is accomplished by adjusting the value of Vramp. However, those skilled in the art will realize that other techniques can be used to reduce the power amplifier supply in response to the comparison at step 740. In one embodiment, processing can then loop back to decision block 740 to once again determine if the power level is too high.

If at decision block 740, it is determined that the power spectral density is not too high, then at decision block 745, the current output power is examined to determine if it is lower than a desired level. If the current output power is lower than desired, or below a desired threshold level, processing continues at step 760 where the voltage level of the power amplifier supply can be increased. In one embodiment, processing can then loop back to decision block 740. If the voltage level is not too low, the voltage level can simply be maintained at block 770. Those skilled in the art will appreciate that the exact sequencing and looping illustrated in FIG. 7 is for the purposes of example and not limitation. For instance, the power spectral density could be compared to a lower threshold and then an upper threshold rather than the illustrated sequence. In addition, the looping can take place after both decision blocks or may not exist at all. Thus, other variations of the flow are anticipated and the present invention is not limited to any particular method.

Processing is then completed and the process 700 can be repeated periodically. In the preferred embodiment, process 700 is invoked during the ramp up and ramp down times of the transmitter. However, in other embodiments, the process 700 can be invoked at other times.

The present invention has been described using detailed descriptions of embodiments thereof that are provided by way of example and are not intended to limit the scope of the invention. The described embodiments comprise different features, not all of which are required in all embodiments of the invention. Some embodiments of the present invention utilize only some of the features or possible combinations of the features. Variations of embodiments of the present invention that are described and embodiments of the present invention comprising different combinations of features noted in the described embodiments will occur to persons of the art. The scope of the invention is limited only by the following claims.

1. A method of controlling the output of a power amplifier to prevent loop saturation, the method comprising the steps of:
detecting the output signal of the power amplifier;
converting the detected output signal from analog to digital;
conducting a transformation on the digital signal to obtain the frequency characteristics of the signal;
comparing the power of the signal at a particular frequency to a threshold value; and
adjusting the output of the power amplifier based on the comparison of the power of the signal and the threshold value.

2. The method of claim 1, wherein the transformation of the digital signal is performed by conducting a Fast Fourier Transform.

3. The method of claim 1, wherein the particular frequency is approximately 400 kHz and the step of comparing the power of the signal to the threshold value is performed by examining the power of the signal at 400 kHz.

4. The method of claim 1, wherein the step of detecting the output signal of the amplifier is performed during the ramp up time of the power amplifier.

5. The method of claim 1, wherein the step of detecting the output signal of the amplifier is performed during the ramp down time of the power amplifier.

6. The method of claim 1, wherein the power amplifier transmits during a time slot and the step of detecting the output signal of the amplifier is performed only during a portion of the time slot.

7. The method of claim 1, wherein the step of adjusting the output of the power amplifier further comprises the steps of:
generating a ramp voltage;
detecting a supply signal, the supply signal being related to the level of the supply voltage provided to the power amplifier;
decreasing the supply voltage to the power amplifier when the supply signal approaches the ramp voltage; and
changing the value of the ramp voltage based on the comparison of the power of the signal and the threshold value.

8. The method of claim 7, wherein the ramp voltage is decreased when the power of the signal approaches the threshold value.

9. The method of claim 7, wherein the ramp voltage is increased when the power of the signal is below the threshold value.

10. The method of claim 7, wherein power amplifier is powered by a battery and the ramp voltage is modified based on the current voltage level of the battery.

11. The method of claim 7, wherein the temperature of the power amplifier is monitored and the ramp voltage is modified based on the current temperature of the power amplifier.

12. The method of claim 1, wherein the step of adjusting the output of the power amplifier further comprises the steps of:
generating a bias voltage to drive the power amplifier; and
changing the value of the bias voltage based on the comparison of the power of the signal and the threshold value.

13. An apparatus for controlling the output of a power amplifier to prevent loop saturation, the apparatus comprising:
a voltage detector coupled to the output of the power amplifier and operative to detect the output signal of the power amplifier;
an analog to digital converter for converting the detected output signal from analog to digital;
a processor operative to:
convert at least a portion of the detected digital signal into the frequency domain;
compare the power of the converted signal at a particular frequency to a threshold value; and
adjusting the output of the power amplifier based on the results of the comparison.

14. The apparatus of claim 13, wherein the analog to digital converter and the processor are included in a base band processor.

15. The apparatus of claim 14, wherein the processor includes a Fast Fourier Transform function and is operative to convert at least a portion of the detected digital signal by conducting a Fast Fourier Transform.

16. The apparatus of claim 15, wherein the base band processor includes a ramp voltage output and the processor is operative to adjust the output of the power amplifier by providing the ramp voltage to an integrator that compares a supply signal representative of a supply voltage to the power amplifier with the ramp voltage and decreases the supply voltage to the power amplifier when the supply signal approaches the ramp voltage.

17. The apparatus of claim 15, wherein the base band processor includes a bias voltage output and the processor is operative to adjust the output of the power amplifier by providing adjusting the value of the bias voltage.

18. A mobile station for use in a cellular system, the mobile station comprising:
a power amplifier having an output signal;
a voltage detector coupled to the output of the power amplifier for detecting the output signal and having a detected signal output;
an analog to digital converter electrically coupled to the output of the voltage detector for receiving the detected signal and for converting the detected signal from analog to a digital signal and providing the digital signal to a digital output;
a processor coupled to output of the analog to digital converter for receiving the digital output, the processor being operative to:
convert at least a portion of the digital signal into the frequency domain;
compare the power of the converted signal at a particular frequency to a threshold value; and
adjusting the output of the power amplifier based on the comparison.

19. The mobile station of claim 18, wherein the voltage detector includes a coupler that obtains a signal that is as low as −30 dB ( 1/1000) of the output signal.

20. The mobile station of claim 19, wherein the coupler is etched into a circuit board housing the voltage detector.
